(19) United States
(12) Patent Application Publication
(10) Pub. No.: US 2026/0080935 A1
(43) Pub. Date: Mar. 19, 2026

(54) MEMORY DEVICE

(71) Applicant: Kioxia Corporation, Tokyo (JP)

(72) Inventors: Tomone SASAKI, Hiratsuka Kanagawa (JP); Masaharu WADA, Yokohama Kanagawa (JP)

(73) Assignee: Kioxia Corporation, Tokyo (JP)

(21) Appl. No.: 19/070,354

(22) Filed: Mar. 4, 2025

(30) Foreign Application Priority Data
Sep. 18, 2024 (JP) 2024-161141

(51) Int. Cl. G11C 11/4096; G11C 11/4074; G11C 11/4091

(52) U.S. Cl. CPC G11C 11/4096; G11C 11/4074; G11C 11/4091

(57) ABSTRACT

First and second inverters between first and second nodes respectively includes a third transistor coupled to a third node and a fifth transistor coupled to a fourth node. A sixth transistor is coupled between the fifth transistor and the third node. A seventh transistor is coupled between the third transistor and the fourth node. An eighth transistor is coupled to the third transistor and the third node. A ninth transistor is coupled to the fifth transistor and the fourth node. A voltage at gates of the sixth and seventh transistors is lowered at a first time. A voltage at gates of the eighth and ninth transistors is lowered. The voltage at the gates of the sixth and seventh transistors is raised after the first time and before a state of first and second voltages applied to the first and second nodes is formed.

### CROSS-REFERENCE TO RELATED APPLICATIONS

This application is based upon and claims the benefit of priority from Japanese Patent Application No. 2024-161141, filed Sep. 18, 2024, the entire contents of which are incorporated herein by reference.

### FIELD

Embodiments described herein relate generally to memory devices.

### BACKGROUND

As a memory device, a dynamic random access memory (DRAM) is known. A memory cell of the DRAM includes a capacitor and a transistor. The memory cell stores data, based on the charge stored in the capacitor. The potential based on the data stored in a memory cell of a data read target is amplified by a sense amplifier, and the stored data is determined thereby.

### BRIEF DESCRIPTION OF THE DRAWINGS

FIG. 1 illustrates functional blocks of a memory device according to a first embodiment and components relevant thereto.

FIG. 2 illustrates components and coupling of the components of a memory cell of the memory device according to the first embodiment.

FIG. 3 illustrates components and coupling of the components of part of a sense amplifier of the memory device according to the first embodiment.

FIG. 4 schematically illustrates potentials of several interconnects, nodes, and signals of the memory device according to the first embodiment during data read along time.

FIG. 5 schematically illustrates potentials of several nodes and signals of memory devices according to the first embodiment and for reference during a part of data read along time.

FIG. 6 schematically illustrates potentials of several interconnects, nodes, and signals of a memory device according to a modification of the first embodiment during data read along time.

FIG. 7 illustrates components and coupling of the components of part of a sense amplifier of the memory device according to a second embodiment.

FIG. 8 schematically illustrates potentials of several interconnects, nodes, and signals of the memory device according to the second embodiment during data read along time.

FIG. 9 schematically illustrates potentials of several nodes and signals of the memory device according to the second embodiment during a part of data read along time.

FIG. 10 schematically illustrates potentials of several interconnects, nodes, and signals of a memory device according to a modification of the second embodiment during data read along time.

### DETAILED DESCRIPTION

In general, according to one embodiment, a memory device includes a capacitor, a first transistor, a first inverter circuit, a second inverter circuit, a sixth transistor, a seventh transistor, an eighth transistor, and a ninth transistor. The first transistor is coupled to the capacitor at a first end. The first inverter circuit is coupled between a first node and a second node, and includes a p-type second transistor and an n-type third transistor coupled in series at a third node. The second inverter circuit is coupled between the first node and the second node, and includes a p-type fourth transistor and an n-type fifth transistor coupled in series at a fourth node. The sixth transistor is coupled between a gate of the fifth transistor and the third node and between a second end of the first transistor and the third node. The seventh transistor is coupled between a gate of the third transistor and the fourth node. The eighth transistor is coupled between the gate of the third transistor and the third node. The ninth transistor is coupled between the gate of the fifth transistor and the fourth node. A voltage applied to a gate of the sixth transistor and a gate of the seventh transistor is lowered at a first time. A voltage applied to a gate of the eighth transistor and a gate of the ninth transistor is lowered at a second time. A state in which a first voltage is applied to the first node and a second voltage lower than the first voltage is applied to the second node is formed at a third time. The voltage applied to the gate of the sixth transistor and the gate of the seventh transistor is raised at a fourth time, which is after the first time and before the third time.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

The specification and the claims, when mentioning that a particular (first) component is “coupled” to another (second) component, intend to cover both the form of the first component directly coupled to the second component and the form of the first component coupled to the second component via one or more components which are always or selectively conductive.

### 1. First Embodiment

### 1.1. Structure (Configuration)

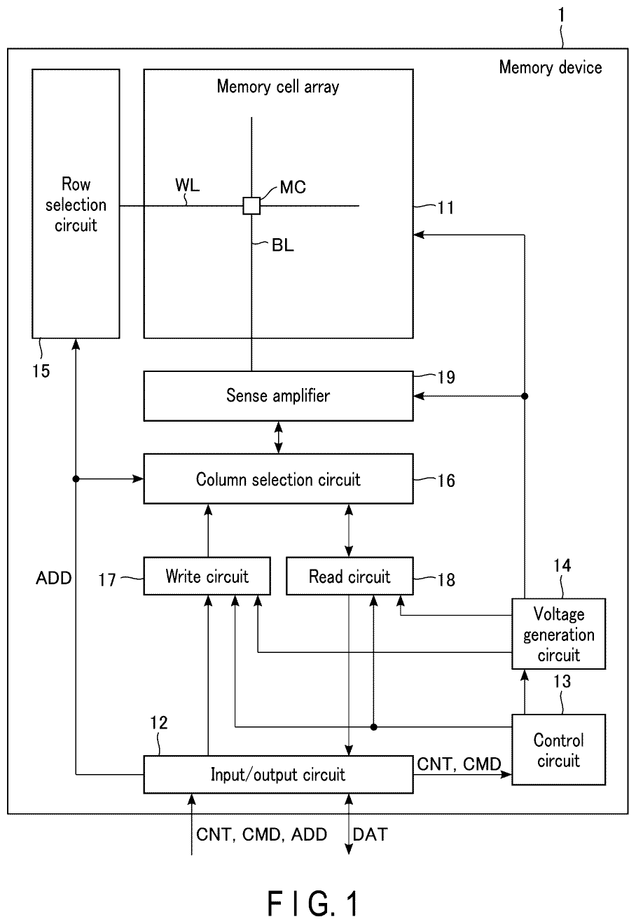

FIG. 1 illustrates a functional block of a memory device according to a first embodiment. The memory device 1 is a device that stores data. The memory device 1 includes a memory cell array 11, an input/output circuit 12, a control circuit 13, a voltage generation circuit 14, a row selection circuit 15, a column selection circuit 16, a write circuit 17, a read circuit 18, and a sense amplifier 19.

The memory cell array 11 includes a plurality of memory cells MC, a plurality of word lines WL, and a plurality of bit lines BL. Each memory cell MC is capable of storing 1-bit data. Each memory cell MC is coupled to a single bit line BL and a single word line WL. The memory cell MC is coupled between the bit line BL and the plate line PL (not illustrated). The word line WL is associated with a row. The bit line BL is associated with a column. Through selection of a single row and a single column, a single memory cell MC is specified.

The input/output circuit 12 is a circuit that inputs and outputs data and signals. The input/output circuit 12 receives, from outside the memory device 1, and, in one example, from a memory controller, a control signal CNT, a command CMD, an address signal ADD, and data DAT. The input/output circuit 12 outputs data DAT. The data DAT is data to be written in the case of data writing in the memory device 1. The data DAT is read data in the case of data reading from the memory device 1.

The control circuit 13 is a circuit that controls the operation of the memory device 1. The control circuit 13 receives a command CMD and a control signal CNT from the input/output circuit 12. The control circuit 13 controls the write circuit 17 and the read circuit 18 based on control instructed by the command CMD and the control signal CNT.

The voltage generation circuit 14 is a circuit that generates various voltages used in the memory device 1. The voltage generation circuit 14 generates multiple voltages with different magnitudes under the control of the control circuit 13. The voltage generation circuit 14 supplies the generated voltages to the memory cell array 11, the write circuit 17, the read circuit 18, and the sense amplifier 19.

The row selection circuit 15 is a circuit that selects a row of a memory cell MC. The row selection circuit 15 receives an address signal ADD from the input/output circuit 12. The row selection circuit 15 makes a single word line WL associated with a row designated by the received address signal ADD a selected state, using a voltage received from the voltage

The column selection circuit 16 is a circuit that selects a column of a memory cell MC. The column selection circuit 16 receives an address signal ADD from the input/output circuit 12. The column selection circuit 16 makes a bit line BL associated with a column designated by the received address signal ADD a selected state, using a voltage received from the voltage generation circuit 14.

The write circuit 17 is a circuit that performs control for writing data into the memory cells MC. The write circuit 17 receives data to be written from the input/output circuit 12. The write circuit 17 supplies, based on the control and data of the control circuit 13, the voltage received from the voltage generation circuit 14 to the column selection circuit 16.

The read circuit 18 is a circuit that performs control for reading data from the memory cells MC. The read circuit 18 determines what data is stored in memory cells MC based on the control of the control circuit 13. The determined data is supplied to the input/output circuit 12. The read circuit supplies control signals to the sense amplifier 19.

The sense amplifier 19 is a circuit for determining what data is stored in the memory cell MC. The sense amplifier 19 includes a plurality of sense amplifier circuits SAC (not illustrated). The sense amplifier 19 receives a plurality of voltages from the voltage generation circuit 14, and operates using the received voltages. During data read, the sense amplifier 19 amplifies a potential of a bit line BL to determine data stored in the memory cell MC of a data read target. The determined data is supplied to the input/output circuit 12.

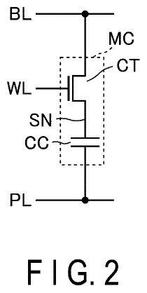

FIG. 2 illustrates components and coupling of the components of the memory cell according to the first embodiment. Hereinafter, one of a source and a drain of a transistor may be referred to as one end of the transistor, and the other of the source and the drain may be referred to as the other end of the transistor.

As illustrated in FIG. 2, each memory cell MC includes a cell capacitor CC and an n-type metal-oxide-semiconductor field-effect transistor (MOSFET) CT. The cell capacitor CC is coupled to, at one end, a plate line PL, and is coupled to, at another end, one end of the transistor CT. The cell capacitor CC stores data using a charge stored in a node coupled to the transistor CT. A node of the cell capacitor CC that is coupled to the transistor CT may be hereinafter referred to as a “storage node SN”.

Whether or not the storage node SN stores a charge is associated with a state in which the memory cell MC stores “1” data, or a state in which “0” data is stored. Hereinafter, as an example, the state in which the storage node SN is relatively positively charged will be treated as a state in which the memory cell MC stores “1” data, and the state in which the storage node SN is not relatively positively charged will be treated as a state in which the memory cell MC stores “0” data.

The transistor CT is coupled to, at the other end, a single bit line BL, and is coupled to, at its gate, a single word line WL.

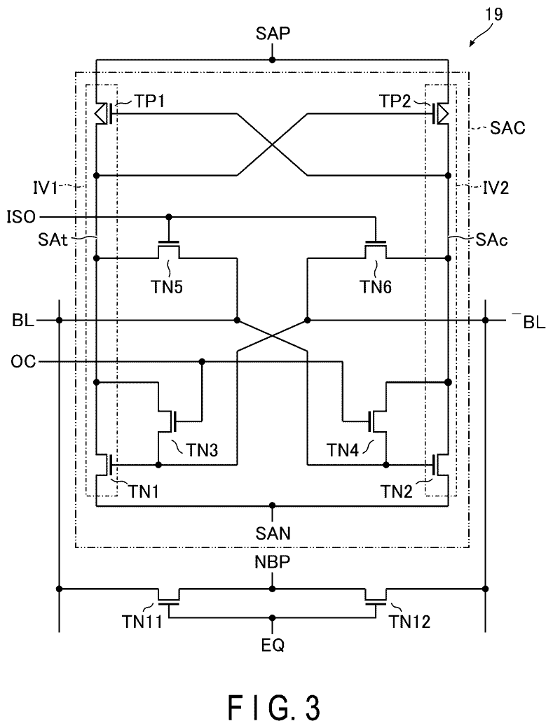

FIG. 3 illustrates components and coupling of the components of part of the sense amplifier according to the first embodiment. As described above, the sense amplifier 19 includes a plurality of sense amplifier circuits SAC. FIG. 3 only illustrates a single sense amplifier circuit SAC.

As illustrated in FIG. 3, each sense amplifier circuit SAC is coupled to a single bit line BL and a node ⁻BL. Hereinafter, the node ⁻BL may be referred to as a complementary bit line ⁻BL. The complementary bit line ⁻BL functions as a node having a reference potential. The reference potential is used to determine data stored in a memory cell MC of a data read target.

The sense amplifier circuit SAC includes p-type MOSFETs TP1 and TP2 and n-type MOSFETS TN1, TN2, TN3, TN4, TN5, and TN6. The sense amplifier 19 further includes transistors TN21 and TN22.

The transistor TP1 is coupled between a node SAP and a node SAt. The node SAP receives a voltage, or, in one example, a voltage from the voltage generator 14. The node SAP receives a dynamically selected one of power-supply voltages Vddsa and Vddsa/2. The power-supply voltage Vddsa may have the same magnitude as a power-supply voltage Vdd, which is used in the memory device 1, or may have a different magnitude from that of the power-supply voltage Vdd. The transistor TP1 is coupled to a node SAc at a gate. The transistor TP1 has a certain magnitude of ON resistance while it is on. The ON resistance of a transistor is a resistance of the transistor while it is on.

The transistor TN1 is coupled between the node SAt and the node SAN. The node SAN receives a voltage, or, in one example, a voltage from the voltage generator 14. The node SAN receives a dynamically selected one of voltages including power-supply voltage Vddsa/2 and a ground (or, common) voltage Vss. In one example, the ground voltage Vss is 0 V, and the following description is based on this example. The transistor TN1 is coupled to a single complementary bit line ⁻BL at a gate. The transistor TN1 has a certain magnitude of ON resistance.

The transistor TP2 is coupled between the node SAP and a node SAc. The transistor TP2 is coupled to the node SAt at a gate. The transistor TP2 has an ON resistance of a magnitude that is substantially identical to that of the transistor TP1. Herein, characteristics of two components being “substantially the same” means permitting cases where the two components are formed in an attempt to be the same, but are not completely the same due to unavoidable reasons such as technical limitations for forming the components and/or limitations on technique for measuring.

The transistor TN2 is coupled between the node SAc and the node SAN. The transistor TN2 is coupled to the bit line BL at a gate. The transistor TN2 has an ON resistance of a magnitude that is substantially identical to that of the transistor TN1.

The transistor TN3 is coupled between the node SAt and the gate of the transistor TN1. The transistor TN3 receives a signal OC at a gate. In one example, the signal OC is supplied from the read circuit 18.

The transistor TN4 is coupled between the node SAc and the gate of the transistor TN2. The transistor TN4 receives the signal OC at a gate.

The transistor TN5 is coupled between the node SAt and the bit line BL. The transistor TN5 receives a signal ISO at a gate. In one example, the signal ISO is supplied from the read circuit 18.

The transistor TN6 is coupled between the node SAC and the complementary bit line BL. The transistor TN6 receives the signal ISO at a gate.

The transistor TN11 is coupled between at least one bit lines BL and a node NBP. The node NBP receives a pre-charge voltage Vpc from the voltage generation circuit 14. The pre-charge voltage Vpc, which is obtained by (Vddsa−Vss)/2, is Vddsa/2 based on an example in which the ground voltage Vss is 0 V, and also functions as a reference voltage. The transistor TN11 receives a signal EQ at a gate. In one example, the signal EQ is supplied from the read circuit 18.

The transistor TN12 is coupled between at least one complementary bit line ⁻BL and the node NBP. The transistor TN12 receives the signal EQ at a gate.

The transistors TP1 and TN1 configure an inverter circuit IV1, and the transistors TP2 and TN2 configure an inverter circuit IV2. While the transistors TN5 and TN6 are on, the inverter circuit IV1 and the inverter circuit IV2 are “cross-coupled”. That is, an input node and an output node of the inverter circuit IV1 are respectively coupled to an output node and an input node of the inverter circuit IV2.

### 1.2. Operation

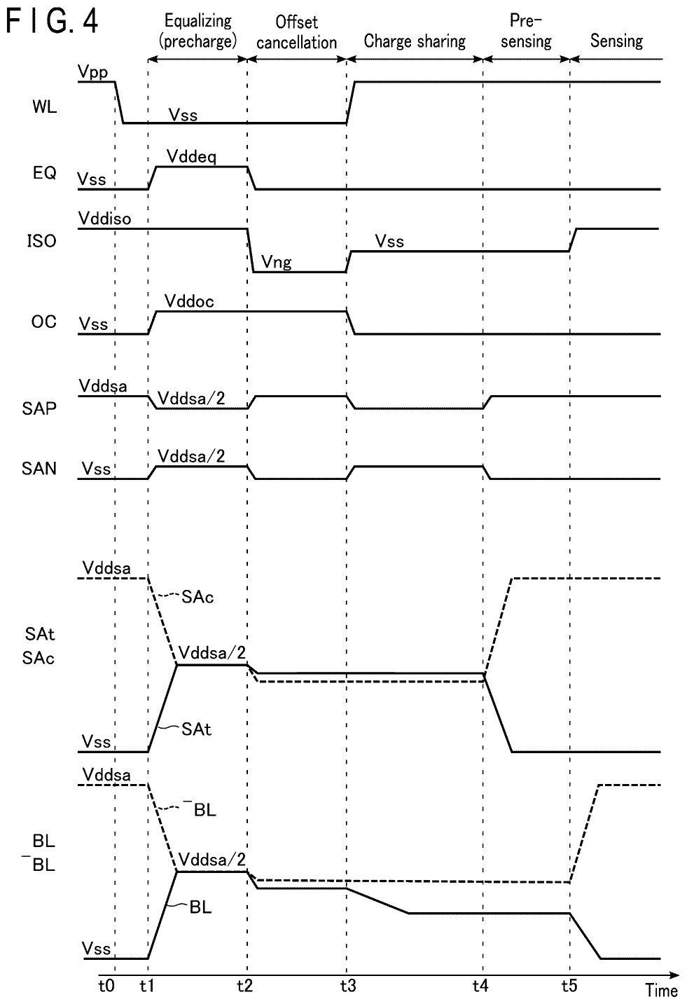

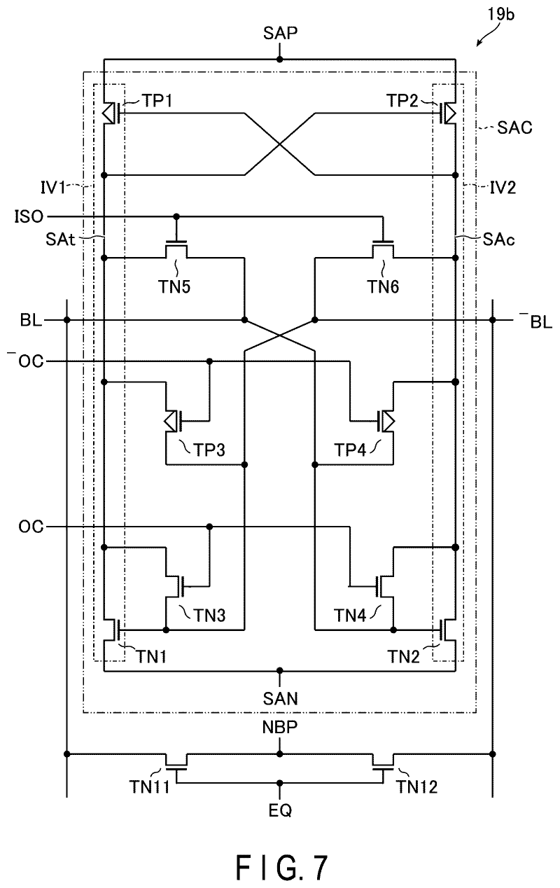

FIG. 4 schematically illustrates potentials of several interconnects, nodes, and signals of the memory device according to the first embodiment during data read along time. Hereinafter, a memory cell MC of a data read target may be referred to as a “selected memory cell MC”. A word line WL whose potential is shown in FIG. 4 is a word line WL coupled to the selected memory cell MC, and may be hereinafter referred to as a “selected word line WL”. A bit line BL whose potential is shown in FIG. 7 is a bit line BL coupled to the selected memory cell MC during data read, and may be hereinafter referred to as a “selected bit line BL”. A complementary bit line ⁻BL coupled to a sense amplifier circuit SAC coupled to the selected bit line BL may be referred to as a “selected complementary bit line ⁻BL”. Through application of a voltage to an illustrated interconnect or an interconnect that transmits a signal, this interconnect has a potential of substantially the same magnitude as that of the applied voltage. For example, in order for an interconnect to have a power-supply potential Vdd, the power-supply voltage Vdd is applied to that interconnect.

The potentials of the respective interconnects and nodes at the start of the period illustrated in FIG. 4 are as follows. The selected word line WL has a power-supply potential Vpp. The power-supply potential Vpp is an internal power-supply potential, and, in one example, has a magnitude different from that of a potential (or, power-supply potential) Vdd of the power-supply voltage Vdd. Since the selected word line WL has the power-supply potential Vpp, the transistor CT of the selected memory cell MC is on, and the cell capacitor CC of the selected memory cell MC is coupled to the selected bit line BL.

The signal EQ has a potential (or, ground potential) Vss of substantially the same magnitude as that of the ground voltage Vss. Thus, the transistors TN11 and TN12 are off, and neither the selected bit line BL nor the selected complementary bit line ⁻BL is coupled to the node NBP of a pre-charge potential Vpc.

The signal ISO has a power-supply potential Vddiso. The power-supply potential Vddiso is an internal power-supply potential, and, in one example, has a magnitude different from that of the power-supply potential Vdd. A transistor TN5 is on with the power-supply potential Vddiso at its gate, and the selected bit line BL is coupled to the node SAt via the transistor TN5 that is on. Thus, the selected bit line BL and the node SAt have substantially the same potential. The transistor TN6 is on with the power-supply potential Vddiso at its gate, and the selected complementary bit line ⁻BL is coupled to the node SAc via the transistor TN6 that is on. Thus, the selected complementary bit line ⁻BL and the node SAc have substantially the same potential.

The signal OC is has the ground potential Vss. The transistor TN3 is off with the ground potential Vss at its gate, and thus the gate of the transistor TN1 is decoupled from the node SAt. The transistor TN4 is off with the ground potential Vss at its gate, and thus the gate of the transistor TN2 is decoupled from the node SAC.

The node SAP has the power-supply potential Vddsa, and the node SAN has the ground potential Vss. Therefore, the sense amplifier circuit SAC is supplied with the power supply and is on, and, in other words, in an operable state.

Based on such states of the potentials, one of the selected bit line BL and the selected complementary bit line ⁻BL has the power-supply potential Vddsa, and the other has the ground potential Vss. Which of the selected bit line BL and the selected complementary bit line ⁻BL has the power-supply potential Vddsa depends on whether the selected memory cell MC stores “0” data or “1” data.

When the selected memory cell MC stores “0” data, the selected bit line BL has the ground potential Vss, and the storage node SN has the ground potential Vss. On the other hand, when the selected memory cell MC stores “1” data, the selected bit line BL has the power-supply potential Vddsa, and the storage node SN has the power-supply potential Vddsa. Hereinafter, the case where the selected memory cell MC stores “0” data may be referred to as “0-data storage case”, and the case where the selected memory cell MC stores “1” data may be referred to as “1-data storage case”. FIG. 4 illustrates the “0-data storage case.

At time t0, the potential of the selected word line WL is brought to the ground potential Vss. Thus, the transistor CT of the selected memory cell MC is turned off, and the cell capacitor CC of the selected memory cell MC is decoupled from the selected bit line BL. The potential of the selected word line WL may be brought to a negative potential.

In the data read, time t1 to time t2 is a period of equalizing. At time t1, the potential of the node SAP is brought to the potential Vddsa/2 and the potential of the node SAN is brought to the potential Vddsa/2. Therefore, the sense amplifier circuit SAC is not supplied with the power supply, and does not have the function to amplify potentials. A voltage applied to the node SAP and the node SAN is (Vddsa+Vss)/2. Based on a case where the ground voltage Vss is 0 V, the voltage applied is the voltage Vddsa/2.

At time T1, the potential of the signal EQ is set to a power-supply potential Vddeq. The power-supply potential Vddeq is an internal power-supply potential, and, in one example, has a magnitude different from that of the power-supply potential Vdd. With the power-supply potential Vddeq at the gates, the transistors TN1 and TN2 are turned on, and the selected bit line BL and the selected complementary bit line ⁻BL are coupled to the node NBP. As a result, both the selected bit line BL and the selected complementary bit line ⁻BL are equalized to the same potential. Specifically, both the selected bit line BL and the selected complementary bit line ⁻BL are pre-charged to the potential of the pre-charge voltage Vpc, in other words, the potential Vddsa/2.

At time t1, the potential of the signal OC is set to a power-supply potential Vddoc. The power-supply potential Vddoc is an internal power-supply potential, and, in one example, has a magnitude different from that of the power-supply potential Vdd. With the power-supply potential Vddoc at the gates, the transistors TN3 and TN4 are turned on. Therefore, the node SAt is coupled to the selected complementary bit line ⁻BL with the transistor TN3 that is on, and the node SAc is coupled to the selected bit line BL with the transistor TN4 that is on.

A period from time t2 to time t3 is a period for offset cancellation. At time t2, the potential of the signal EQ is set to the ground potential Vss. As a result, the precharge of the selected bit line BL and the selected complementary bit line ⁻BL ends.

At time t2, the potential of the signal ISO is set to a potential Vng. The potential Vng is lower than the ground potential Vss. Based on an example in which the ground potential Vss is 0 V, the potential Vng is a negative potential. With the potential Vng at the gate, the transistors TN5 and TN6 are turned off.

Since the transistor TN5 is off during the offset cancellation, the selected bit line BL is decoupled from the node SAt, that is, isolated. Furthermore, since the transistor TN6 is off, the selected complementary bit line ⁻BL is decoupled from the node SAc, that is, isolated. Therefore, the inverter circuit IV1 (or, transistors TP1 and TN1) and the inverter circuit IV2 (or, transistors TP2 and TN2) are not cross-coupled.

On the other hand, as described above, the node SAt is coupled to the selected complementary bit line ⁻BL by the transistor TN3 that is on. Therefore, the potential of the node SAt is transferred to the selected complementary bit line ⁻BL, and the node SAt has substantially the same potential as the potential of the selected complementary bit line ⁻BL. In addition, the node SAc is coupled to the selected bit line BL by the transistor TN4 that is on. Therefore, the potential of the node SAc is transferred to the selected bit line BL, and the node SAc has substantially the same potential as the potential of the selected bit line BL.

At time t2, the potential of the node SAP is set to the power supply potential Vddsa, and the potential of the node SAN is set to the ground potential Vss.

By the end of the precharge and the start of the isolation at time t2, the potentials of the selected bit line BL and the selected complementary bit line ⁻BL change from the precharge potential (Vddsa/2). During this change, offset cancellation is performed by the functions of the transistors TN3 and TN4 that are on. That is, the transistor TN1 is on by the transistor TN3, and thus, the on-resistance of the transistor TN1 is formed between the node SAt and the node SAN. Therefore, a potential based on the ratio of the on-resistance of the transistor TP1 and the on-resistance of the transistor TN1 is generated at the node SAt. In general, a p-type MOSFET and an n-type MOSFET have different on-resistances, and the on-resistance of the n-type MOSFET is smaller than the on-resistance of the p-type MOSFET. Therefore, the potential of the node SAt is not an intermediate value between the potential of the node SAP and the potential of the node SAN, but is a potential lower than the intermediate value.

In addition, the transistor TN2 is on by the transistor TN4, and thus, the on-resistance of the transistor TN2 is formed between the node SAc and the node SAN. Therefore, a potential based on the ratio of the on-resistance of the transistor TP2 and the on-resistance of the transistor TN2 is generated at the node SAC. Therefore, for the same reason as described for the node SAt, the potential of the node SAc is not an intermediate value between the potential of the node SAP and the potential of the node SAN, but is a potential lower than the intermediate value.

The change in the potential of the node SAt due to the offset cancellation also changes the potential of the selected complementary bit line ⁻BL coupled to the node SAt through the transistor TN3. That is, the potential of the node SAt is reflected on the potential of the selected complementary bit line ⁻BL. The change in the potential of the node SAc due to the offset cancellation also changes the potential of the selected bit line BL coupled to the node SAc through the transistor TN4. That is, the potential of the node SAC is reflected on the potential of the selected bit line BL. One of the potential of the selected bit line BL and the potential of the selected complementary bit line ⁻BL falls from the potential Vddsa/2 by a positive magnitude ΔV1, and the other falls from the potential Vddsa/2 by a positive magnitude ΔV2.

A difference between ΔV1 and ΔV2 leads to an imbalance between a difference (or, margin) between the potential of the selected bit line BL and the reference potential when the selected bit line BL has the higher potential and the difference between the potential of the selected bit line BL and the reference potential when the selected bit line BL has the lower potential. The difference between ΔV1 and ΔV2 is based on the difference between the on-resistances of the transistors TP1 and TN1 and the difference between the on-resistances of the transistors TP2 and TN2. Therefore, at the start of the subsequent charge sharing, the nodes SAt and SAc have potentials based on the difference between the on-resistances of the transistors TP1 and TN1 and the difference between the on-resistances of the transistors TP2 and TN2, respectively. Then, the selected complementary bit line ⁻BL and the selected bit line BL are charged by the nodes SAt and SAC having such potentials. Sensing is performed based on the potentials of the selected bit line BL and the selected complementary bit line ⁻BL charged to such potentials. Therefore, the difference between the on-resistances of the transistors TP1 and TN1 and the difference between the on-resistances of the transistors TP2 and TN2 can be equivalently canceled (or, compensated).

A period from time t3 to time t4 is a period of charge sharing. At time t3, the potential of the node SAP is set to the potential Vddsa/2, and the potential of the node SAN is set to the potential Vddsa/2. As a result, the sense amplifier circuit SAC cannot amplify the potentials.

At time t3, the potential of the signal OC is set to the ground potential Vss. With the ground potential Vss at the gate, the transistors TN3 and TN4 are turned off. Furthermore, at time t3, the potential of the signal ISO is set to the ground potential Vss. Even with the ground potential Vss at the gate, the transistors TN5 and TN6 are not turned on but remain off.

Since the transistors TN4 and TN5 are off during the charge sharing, the selected bit line BL is decoupled from both the node SAt and the node SAc. In addition, since the transistors TN3 and TN6 are off, the selected complementary bit line ⁻BL is decoupled from both the node SAt and the node SAc.

The transistor TN5 has a parasitic capacitance between the gate and the drain. With this capacitance, when the potential of the gate of the transistor TN5 rises and falls, the potential of the drain (that is, the potential of the node SAt) rises and falls, respectively. Similarly, the transistor TN6 has a parasitic capacitance between the gate and the drain. With this capacitance, when the potential of the gate of the transistor TN6 rises and falls, the potential of the drain (that is, the potential of the node SAc) rises and falls, respectively.

The transistor TN3 has a parasitic capacitance between the gate and the drain. With this capacitance, when the potential of the gate falls by setting the potential of the signal OC to the ground potential Vss at time t3, the potential of the drain (that is, the potential of the node SAt) falls. On the other hand, as the potential of the signal ISO rises at time t3, the potential of the node SAt rises through the parasitic capacitance of the gate and the drain of the transistor TN5. Therefore, the fall in the potential of the node SAt due to the fall in the potential of the signal OC at time t3 is suppressed by the rise in the potential of the signal ISO. The amount of rise in the potential of the node SAt depends on the parasitic capacitance between the gate and the drain of the transistor TN5 and the amount of rise in the potential of the signal ISO. In addition, the amount of rise in the potential of the signal ISO depends on the potential Vng. Therefore, the potential Vng is determined in advance so that the fall in the node SAt due to the fall in the potential of the signal OC is suppressed by the rise in the potential of the signal ISO to a desired extent.

Similarly, the transistor TN4 has a parasitic capacitance between the gate and the drain. With this capacitance, when the potential of the gate falls by setting the potential of the signal OC to the ground potential Vss at time t3, the potential of the drain (that is, the potential of the node SAc) falls. On the other hand, as the potential of the signal ISO rises at time t3, the potential of the node SAc rises through the parasitic capacitance of the gate and the drain of the transistor TN6. Therefore, the fall in the potential of the node SAc due to the fall in the potential of the signal OC at time t3 is suppressed by the rise in the potential of the signal ISO. The amount of rise in the potential of the node SAc depends on the parasitic capacitance between the gate and the drain of the transistor TN6 and the amount of rise in the potential of the signal ISO.

At time t3, the potential of the selected word line WL is set to the potential Vpp. As a result, charge sharing starts. By the charge sharing, the charge accumulated in the selected bit line BL and the charge accumulated in the storage node SN of the selected memory cell MC are shared. As a result, the potential of the selected bit line BL rises or falls based on the data stored in the selected memory cell MC. The potential of the selected bit line BL (and the storage node SN) comes to have a magnitude in a case where the potential of the selected bit line BL and the potential of the storage node SN become equal.

In the “0” data storage case (the case illustrated in FIG. 4), the potential of the selected bit line BL falls toward the potential of the storage node SN, and the potential of the storage node SN rises toward the potential of the selected bit line BL. The selected bit line BL and the storage node SN comes to have a potential of a magnitude reached when the falling potential of the selected bit line BL and the rising potential of the storage node SN become equal. The potential of the selected complementary bit line ⁻BL is maintained.

On the other hand, in the “1” data storage case, the potential of the selected bit line BL rises toward the potential of the storage node SN, and the potential of the storage node SN falls toward the potential of the selected bit line BL. The selected bit line BL and the storage node SN comes to have a potential of a magnitude reached when the rising potential of the selected bit line BL and the falling potential of the storage node SN become equal. The potential of the selected complementary bit line ⁻BL is maintained.

The period from time t4 to time t5 is a pre-sensing period. At time t4, the potential of the node SAP is set to the power supply potential Vddsa, and the potential of the node SAN is set to the ground potential Vss. As a result, the sense amplifier circuit SAC can amplify the potentials. The sense amplifier circuit SAC raises one of the potential of the node SAt and the potential of the node SAc to the power supply potential Vdsa and lowers the other to the ground potential Vss. In the “0” data storage case shown in FIG. 4, the potential of the node SAt is lowered to the ground potential Vss, and the potential of the node SAc is raised to the power supply potential Vddsa. In the “1” data storage case, the potential of the node SAt is raised to the power supply potential Vddsa, and the potential of the node SAc is lowered to the ground potential Vss.

A period after time t5 is a period of sensing (or, main sensing). At time t5, the potential of the signal ISO is set to the power supply potential Vddiso. As a result, the transistors TN5 and TN6 are turned on. Therefore, the node SAt is coupled to the selected bit line BL through the transistor TN5, and the node SAc is coupled to the selected complementary bit line ⁻BL through the transistor TN6. Therefore, in the “0” data storage case illustrated in FIG. 4, the potential of the selected bit line BL is lowered to the ground potential Vss, and the potential of the selected complementary bit line ⁻BL is raised to the power supply potential Vddsa. In the “1” data storage case, the potential of the selected bit line BL is raised to the power supply potential Vddsa, and the potential of the selected complementary bit line ⁻BL is lowered to the ground potential Vss.

1.3. Advantages (advantageous Effects)

According to the first embodiment, it is possible to provide a memory device capable of determining data stored in a memory cell with high reliability as described below.

For comparison, a memory device for reference is described. The memory device for reference includes a sense amplifier circuit SAC of the memory device 1. On the other hand, the memory device for reference is different from the memory device 1 in that the potential of the signal ISO changes.

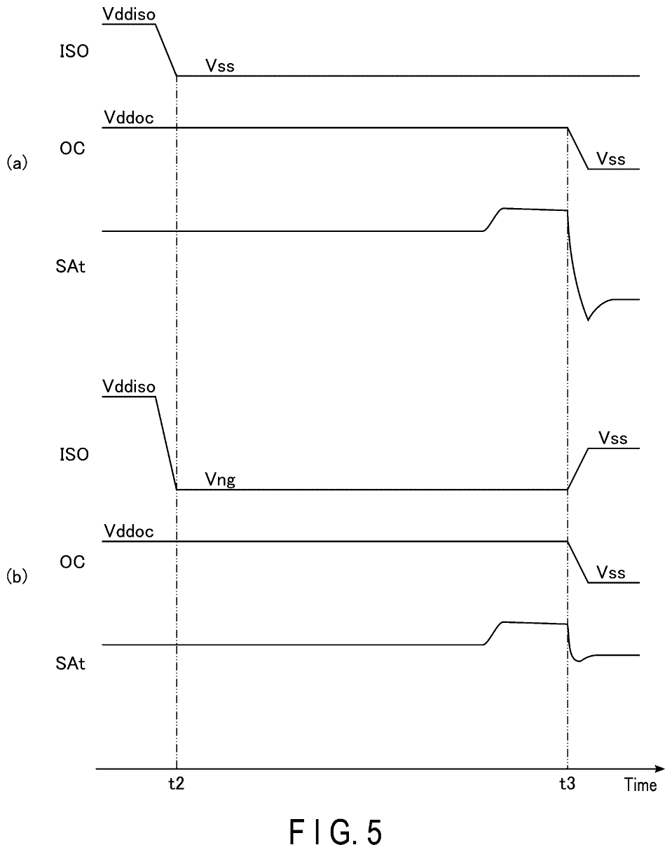

FIG. 5 schematically illustrates potentials during data read of some elements of the first embodiment and the reference memory device along time, and illustrates potentials of signals and nodes. FIG. 5 illustrates potentials of a signal and a node of the memory device for reference in a section (a), and illustrates potentials of a signal and a node of the memory device 1 in a section (b).

By the offset cancellation, the node SAt holds a potential that eliminates a difference between a driving capability (or, driving capacity) of the transistor TP1 and a driving capability of the transistor TN1, and the node SAc holds a potential that eliminates the difference between a driving capability of the transistor TP2 and a driving capability of the transistor TN1 at the time point of the end of the offset cancellation.

In the memory device for reference, the potential of the signal ISO is maintained at the ground potential Vss from time t2 to time t3 onward. As described above with reference to FIG. 4, the potential of the signal OC is set to the ground potential Vss at the time t3 so that the potentials of the nodes SAt and SAc quickly fall from the time t3. Therefore, the state formed by the offset cancellation collapses, and therefore the driving capability of the transistor TP1 becomes larger than the driving capability of the transistor TN1 and the driving capability of the transistor TP2 becomes larger than the driving capability of the transistor TN2. As a result, the potential of the node SAt rises, and a state in which it is easily determined that the memory cell MC stores “1” data occurs. Therefore, it may be erroneously determined that “1” data is stored in the “0” data storage case.

According to the first embodiment, the potential of the signal ISO is set to be lower than the ground potential Vss at the start of offset cancellation, and is raised to the ground potential Vss at substantially the same timing as the potential of the signal OC is lowered to the ground potential Vss. Therefore, the fall in the potential of the node SAt due to the fall in the potential of the signal OC at the time t3 is suppressed by the rise in the potential of the signal ISO. Therefore, as illustrated in the section (b) of FIG. 5, at time t3, the potential of the node SAt has a potential close to the potential immediately before time t3. Therefore, a state formed in a case where “1” data is stored in the “0” data storage case hardly occurs. Therefore, the memory device 1 can read data from the Selected memory cell MC with high reliability.

### 1.4. Modification

The changes in the potential of some interconnects, nodes, and signals shown in FIG. 4 are examples, and it is not essential that changes described as occurring at a certain same time occur at the same time. For example, in order to execute equalization, the changes in the potentials of the signals EQ and OC and the nodes SAP and SAN may not be the same, and a state described as occurring from the time t1 to the time t2 only need to occur during the equalization period.

The potential of the word line WL may be set to the potential Vpp after the time t3.

The potential of the signal ISO may be set to the potential Vng before or after the fall of the potential of the signal EQ to the potential Vss and/or the change in the potentials of the nodes SAP and SAN.

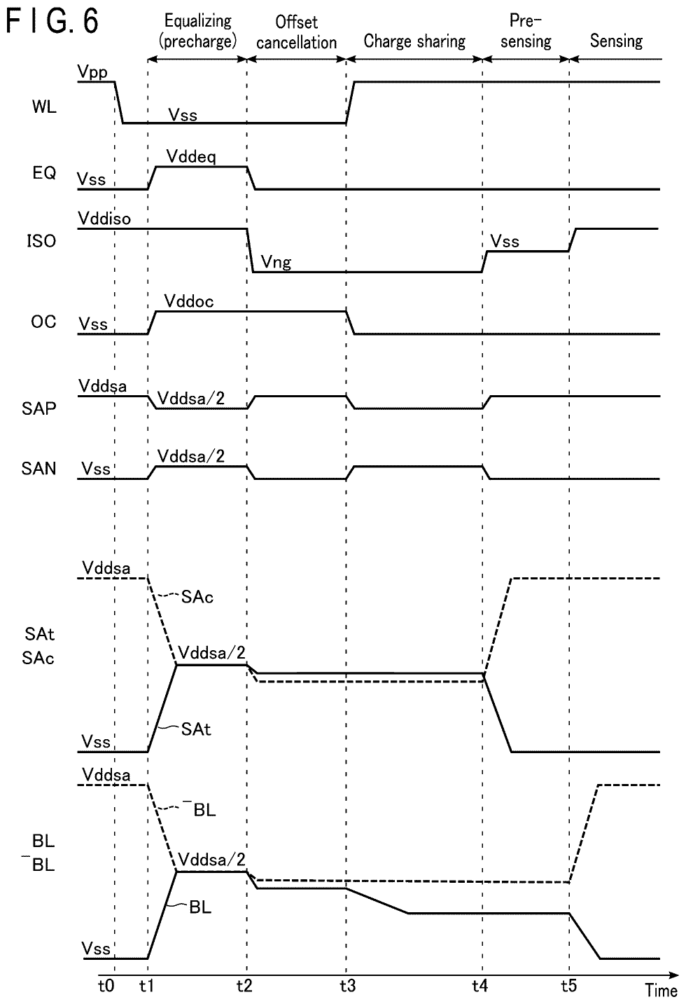

The potential of the signal ISO may be set to the potential Vss before or after the potential of the signal OC falls to the potential Vss. As illustrated in FIG. 6, the potential of the signal ISO may be raised at least before the start of the pre-sensing (time t4). This also provides the advantages described above.

### 2. Second Embodiment

FIG. 7 illustrates some components and coupling of the components of a sense amplifier of a memory device according to a second embodiment. As illustrated in FIG. 7, a sense amplifier circuit SAC of a memory device 1 according to the second embodiment further includes p-type MOSFETs TP3 and TP4.

The transistor TP3 is coupled between the node SAt and the gate of a transistor TN1. The transistor TP3 receives a signal ⁻OC at the gate. The signal ⁻OC has a logic level obtained by inverting the logic level of the signal OC. In one example, the signal ⁻OC is supplied from the read circuit 18. The transistor TP3 has a parasitic capacitance between the gate and the drain, and has a parasitic capacitance of a magnitude similar to the parasitic capacitance between the gate and the drain of a transistor TN3. In one example, the transistor TP3 has, between the gate and the drain, a parasitic capacitance of substantially the same magnitude as the parasitic capacitance between the gate and the drain of the transistor TN3.

The transistor TP4 is coupled between the node SAC and the gate of the transistor TN2. The transistor TP4 receives the signal ⁻OC at the gate. The transistor TP4 has a parasitic capacitance between the gate and the drain, and has a parasitic capacitance of a magnitude similar to the parasitic capacitance between the gate and the drain of the transistor TN4. In one example, the transistor TP4 has, between the gate and the drain, a parasitic capacitance of substantially the same magnitude as the parasitic capacitance between the gate and the drain of the transistor TN4.

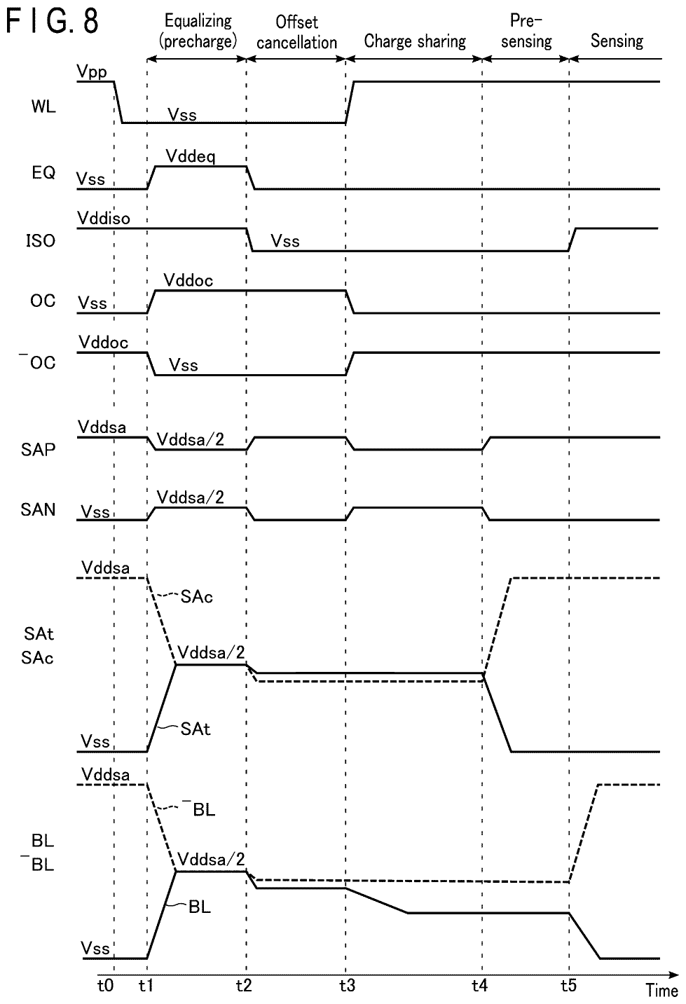

FIG. 8 schematically illustrates potentials during data read of some elements of the memory device along time according to the second embodiment. As shown in FIG. 8, the signal ⁻OC has a change opposite to the change in potential of the signal OC. That is, the signal ⁻OC has the ground potential Vss while the signal OC has the power supply potential Vddoc, and has the power supply potential Vddoc while the signal OC has the ground potential Vss.

The potential of the signal ISO is set to the ground potential Vss at time t2 instead of the potential Vng in the first embodiment, and is maintained at time

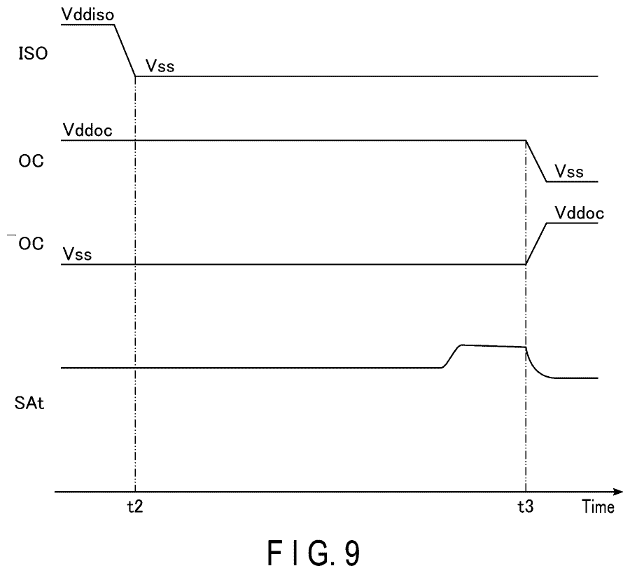

FIG. 9 schematically illustrates potentials of several nodes and signals of the memory device according the second embodiment along time. As described above with reference to FIG. 8 and shown in FIG. 9, at time t3, the potential of the signal ⁻OC is raised from the ground potential Vss to the power supply potential Vddoc.

Due to the parasitic capacitance between the gate and the drain of the transistor TP3, when the potential of the gate rises due to the potential of the signal ⁻OC being set to the power supply potential Vddoc at time t3, the potential of the drain (that is, the potential of the node SAt) rises. On the other hand, as described above with reference to FIG. 4 of the first embodiment, when the potential of the gate falls by setting the potential of the signal OC to the ground potential Vss at time t3 by the parasitic capacitance of the transistor TN3, the potential of the drain (that is, the potential of the node SAt) falls. However, the fall in the potential of the node SAt due to the parasitic capacitance of the transistor TN3 is suppressed by the rise in the potential of the node SAt due to the parasitic capacitance of the transistor TP3. Therefore, even after time t3, the potential of the node SAt is almost the same as the potential before time t3.

Similarly, due to the parasitic capacitance between the gate and the drain of the transistor TP4, when the potential of the gate rises due to the potential of the signal ⁻OC being set to the power supply potential Vddoc at time t3, the potential of the drain (that is, the potential of the node SAc) rises. On the other hand, as described above with reference to FIG. 4 of the first embodiment, when the potential of the gate falls by setting the potential of the signal OC to the ground potential Vss at time t3 by the parasitic capacitance of the transistor TN4, the potential of the drain (that is, the potential of the node SAc) falls. However, the fall in the potential of the node SAc due to the parasitic capacitance of the transistor TN4 is suppressed by the rise in the potential of the node SAc due to the parasitic capacitance of the transistor TP4. Therefore, even after time t3, the potential of the node SAc is almost the same as the potential before time t3.

According to the second embodiment, the transistor TP3 coupled between the node SAt and the gate of the transistor TN1 and the transistor TP4 coupled between the node SAc and the gate of the transistor TN2 are provided, and the transistors TP3 and TP4 receive the signal ⁻OC at the gate. Therefore, the fall in the potentials of the nodes SAt and SAc due to the fall in the potential of the signal OC through the transistors TN3 and TN4 is suppressed by the rise in the potentials of the nodes SAt and SAc due to the rise in potential of the signal ⁻OC through the transistors TP3 and TP4. Therefore, according to the same principle as that of the first embodiment, the memory device 1 can read data from the selected memory cell MC with high reliability.

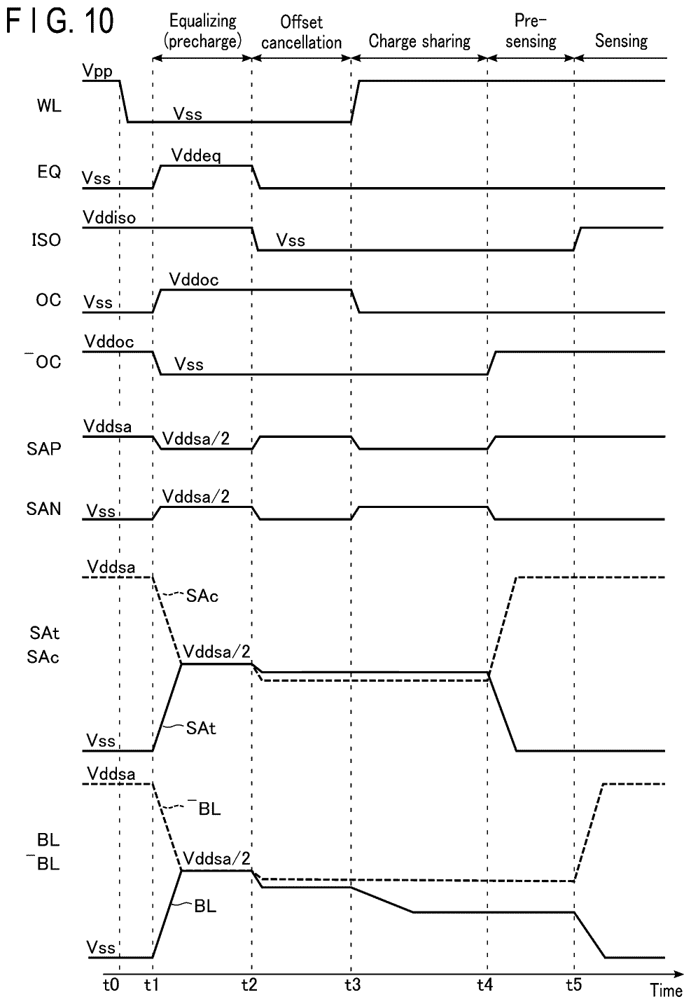

The potential of the signal ⁻OC may be set to the power supply potential Vddoc before or after the potential of the signal OC falls to the potential Vss. As illustrated in FIG. 10, the potential of the signal ⁻OC only need to be raised at least before the start of the pre-sensing (time t4). This also provides the advantages described above.

The second embodiment may be combined with the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A memory device comprising:
a capacitor;
a first transistor coupled to the capacitor at a first end;
a first inverter circuit coupled between a first node and a second node, the first inverter circuit including a p-type second transistor and an n-type third transistor coupled in series at a third node;
a second inverter circuit coupled between the first node and the second node, the second inverter circuit including a p-type fourth transistor and an n-type fifth transistor coupled in series at a fourth node;
a sixth transistor coupled between a gate of the fifth transistor and the third node and between a second end of the first transistor and the third node;
a seventh transistor coupled between a gate of the third transistor and the fourth node;
an eighth transistor coupled between the gate of the third transistor and the third node; and
a ninth transistor coupled between the gate of the fifth transistor and the fourth node, wherein
a voltage applied to a gate of the sixth transistor and a gate of the seventh transistor is lowered at a first time,
a voltage applied to a gate of the eighth transistor and a gate of the ninth transistor is lowered at a second time,
a state in which a first voltage is applied to the first node and a second voltage lower than the first voltage is applied to the second node is formed at a third time, and
the voltage applied to the gate of the sixth transistor and the gate of the seventh transistor is raised at a fourth time to a magnitude that does not turn on the sixth transistor or the seventh transistor, the fourth time being after the first time and before the third time.

2. The memory device according to claim 1, wherein
the voltage applied to the gate of the sixth transistor and the gate of the seventh transistor at the first time is lowered from a voltage for turning on the sixth transistor and the seventh transistor to a voltage for turning off the sixth transistor and the seventh transistor.

3. (canceled)

4. The memory device according to claim 2, wherein
the voltage for turning off the sixth transistor and the seventh transistor is continuously applied to the gate of the sixth transistor and the gate of the seventh transistor from the first time to the fourth time.

5. The memory device according to claim 4, wherein
the voltage applied to the gate of the eighth transistor and the gate of the ninth transistor at the second time is lowered from a voltage for turning on the eighth transistor and the ninth transistor to a voltage for turning off the eighth transistor and the ninth transistor.

6. The memory device according to claim 2, wherein
the voltage applied to the gate of the sixth transistor and the gate of the seventh transistor is raised from a voltage for turning off the sixth transistor and the seventh transistor to a voltage for turning on the sixth transistor and the seventh transistor at a fifth time after the third time.

7. The memory device according to claim 1, wherein
the voltage applied to the gate of the sixth transistor and the gate of the seventh transistor at the fourth time is a voltage for turning off the sixth transistor and the seventh transistor.

8. The memory device according to claim 1, wherein
the voltage applied to the gate of the eighth transistor and the gate of the ninth transistor at the second time is lowered from a voltage for turning on the eighth transistor and the ninth transistor to a voltage for turning off the eighth transistor and the ninth transistor.

9. A memory device comprising:
a capacitor;
a first transistor coupled to the capacitor at a first end;
a first inverter circuit coupled between a first node and a second node, the first inverter circuit including a p-type second transistor and an n-type third transistor coupled in series at a third node;
a second inverter circuit coupled between the first node and the second node, the second inverter circuit including a p-type fourth transistor and an n-type fifth transistor coupled in series at a fourth node;
a sixth transistor coupled between a gate of the fifth transistor and the third node and between a second end of the first transistor and the third node;
a seventh transistor coupled between a gate of the third transistor and the fourth node;
an n-type eighth transistor coupled between the gate of the third transistor and the third node;
an n-type ninth transistor coupled between the gate of the fifth transistor and the fourth node;
a p-type tenth transistor coupled between the gate of the third transistor and the third node; and
a p-type eleventh transistor coupled between the gate of the fifth transistor and the fourth node.

10. The memory device according to claim 9, wherein
a gate of the tenth transistor and a gate of the eleventh transistor receive a third voltage while a gate of the eighth transistor and a gate of the ninth transistor receive a second voltage higher than a first voltage, and
the gate of the tenth transistor and the gate of the eleventh transistor receive a fourth voltage higher than the third voltage while the gate of the eighth transistor and the gate of the ninth transistor receive the first voltage.

11. The memory device according to claim 9, wherein
a voltage applied to a gate of the eighth transistor and a gate of the ninth transistor is lowered at a first time,
a state in which a fifth voltage is applied to the first node and a sixth voltage lower than the fifth voltage is applied to the second node is formed at a second time, and
a voltage applied to a gate of the tenth transistor and a gate of the eleventh transistor is raised at a third time that is between a time before the first time and the second time.

12. The memory device according to claim 11, wherein
the third time is the first time, or is after the first time and before the second time.

13. The memory device according to claim 12, wherein
the voltage applied to the gate of the eighth transistor and the gate of the ninth transistor at the first time is lowered from a voltage for turning on the eighth transistor and the ninth transistor to a voltage for turning off the eighth transistor and the ninth transistor.

14. The memory device according to claim 13, wherein
the voltage applied to the gate of the tenth transistor and the gate of the eleventh transistor at the third time is raised from a voltage for turning on the tenth transistor and the eleventh transistor to a voltage for turning off the tenth transistor and the eleventh transistor.

15. The memory device according to claim 11, wherein
the voltage applied to the gate of the eighth transistor and the gate of the ninth transistor at the first time is lowered from a voltage for turning on the eighth transistor and the ninth transistor to a voltage for turning off the eighth transistor and the ninth transistor.

16. The memory device according to claim 15, wherein
the voltage applied to the gate of the tenth transistor and the gate of the eleventh transistor at the third time is raised from a voltage for turning on the tenth transistor and the eleventh transistor to a voltage for turning off the tenth transistor and the eleventh transistor.
